(19) United States
(12) Patent Application Publication
(10) Pub. No.: US 2019/0148176 A1
(43) Pub. Date: May 16, 2019

(54) SUBSTRATE PROCESSING APPARATUS

(71) Applicant: Tokyo Electron Limited, Tokyo (JP)

(72) Inventors: Koji Tanaka, Kumamoto (JP); Takashi Ikeda, Kumamoto (JP); Hiroyuki Masutomi, Kumamoto (JP)

(21) Appl. No.: 16/167,863

(22) Filed: Oct. 23, 2018

(30) Foreign Application Priority Data
Oct. 24, 2017 (JP) 2017-205550

(51) Int. Cl. H01L 21/67; H01L 21/673

(52) U.S. Cl. CPC H01L 21/6708; H01L 21/67393; H01L 21/6715

(57) ABSTRACT

A substrate processing apparatus according to an embodiment includes a substrate processing tank, a processing liquid supply nozzle, and a pressure regulating plate. The processing liquid supply nozzle is provided in a lower portion within the substrate processing tank, and ejects the processing liquid from a plurality of ejection ports. The pressure regulating plate is provided between the processing liquid supply nozzle and the substrate in the substrate processing tank and has a plurality of holes through which the processing liquid flows. The pressure regulating plate is configured to adjust the inflow pressure of the processing liquid ejected from the processing liquid supply nozzle. In addition, the pressure regulating plate includes ribs that protrude from a processing liquid supply nozzle side surface thereof so as to partition the processing liquid supply nozzle side surface into a plurality of partitioned regions.

### CROSS-REFERENCE TO RELATED APPLICATIONS

This application is based on and claims priority from Japanese Patent Application No. 2017-205550, filed on Oct. 24, 2017 with the Japan Patent Office, the disclosure of which is incorporated herein in its entirety by reference.

### TECHNICAL FIELD

Exemplary embodiments disclosed herein relate to a substrate processing apparatus.

### BACKGROUND

In the related art, there has been known a substrate processing apparatus that supplies a processing liquid in which, for example, nitrogen gas is mixed as bubbles to a processing tank (see, e.g., Japanese Patent Laid-Open Publication No. 2017-069529).

### SUMMARY

A substrate processing apparatus according to an aspect of an embodiment includes a substrate processing tank, a processing liquid supply nozzle, and a pressure regulating plate. The processing liquid supply nozzle is provided in a lower portion within the substrate processing tank, and ejects the processing liquid from a plurality of ejection ports. The pressure regulating plate is provided between the processing liquid supply nozzle and the substrate in the substrate processing tank and has a plurality of holes through which the processing liquid flows. The pressure regulating plate is configured to adjust the inflow pressure of the processing liquid ejected from the processing liquid supply nozzle. In addition, the pressure regulating plate includes ribs that protrude from a processing liquid supply nozzle side surface thereof so as to partition the processing liquid supply nozzle side surface into a plurality of partitioned regions.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic plan view illustrating a substrate processing apparatus according to a first embodiment.

FIG. 2 is a schematic block diagram illustrating a configuration of a supply system of an etching processing tank according to the first embodiment.

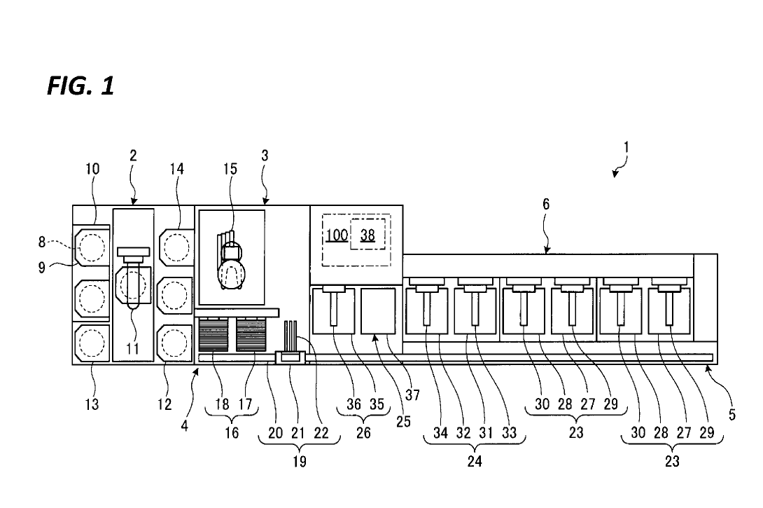

FIG. 1 is a schematic plan view illustrating a pressure regulating plate according to the first embodiment.

FIG. 4 is a schematic cross-sectional view taken along line IV-IV in FIG. 3.

FIG. 5 is a schematic diagram illustrating the state of bubbles contained in the etching liquid ejected from a processing liquid supply nozzle.

FIG. 6 is a schematic plan view illustrating a flow regulating plate according to the first embodiment.

FIG. 7 is a schematic plan view illustrating a flow regulating plate according to a modification.

FIG. 8 is a schematic configuration view illustrating a bubble generating unit according to the first embodiment.

FIG. 9 is a schematic plan view illustrating a pressure regulating plate according to the second embodiment.

FIG. 10 is a schematic plan view illustrating a pressure regulating plate according to the third embodiment.

FIG. 11 is a schematic block diagram illustrating a configuration of an etching processing tank according to a fourth embodiment.

FIG. 12 is a schematic configuration view illustrating the configuration of a bubble generating unit according to the fourth embodiment.

FIG. 13 is a schematic front view of a bubble generating unit according to a fifth embodiment, as viewed in the flow direction of the etching liquid.

FIG. 14 is a schematic cross-sectional view taken along line XIV-XIV in FIG. 13.

FIG. 15 is a view illustrating the bubble generating unit in which the mixing portion has been rotated by 90 degrees from the state illustrated in FIG. 13.

FIG. 16 is a schematic cross-sectional view taken along line XVI-XVI in FIG. 15.

FIG. 17 is a schematic front view of a bubble generating unit according to a modification, as viewed in the flow direction of the etching liquid.

FIG. 18 is a schematic cross-sectional view taken along line XVIII-XVIII in FIG. 17.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

In the above-described substrate processing apparatus, there is room for improvement in that a substrate is uniformly processed by the processing liquid in which bubbles are mixed.

An aspect of an embodiment is to provide a substrate processing apparatus that uniformly etches a substrate.

A substrate processing apparatus according to an aspect of an embodiment includes a substrate processing tank, a processing liquid supply nozzle, and a pressure regulating plate. The processing liquid supply nozzle is provided in a lower portion within the substrate processing tank, and ejects the processing liquid from a plurality of ejection ports. The pressure regulating plate is provided between the processing liquid supply nozzle and the substrate in the substrate processing tank and has a plurality of holes through which the processing liquid flows. The pressure regulating plate is configured to adjust the inflow pressure of the processing liquid ejected from the processing liquid supply nozzle. In addition, the pressure regulating plate includes ribs that protrude from a processing liquid supply nozzle side surface thereof so as to partition the processing liquid supply nozzle side surface into a plurality of partitioned regions.

In the above-described substrate processing apparatus, the pressure regulating plate includes the ribs in a lattice shape.

In the above-described substrate processing apparatus, among the plurality of partitioned regions, a partitioned region on a sidewall side of the substrate processing tank has an area smaller than areas of the other partitioned regions.

In the above-described substrate processing apparatus, the pressure regulating plate has a chamfered portion at an end of each of the holes on the processing liquid supply nozzle side.

The above-described substrate processing apparatus further includes: a flow regulating plate provided between the pressure regulating plate and the substrate and having a slit, and configured to regulate a flow of the processing liquid to the substrate.

The above-described substrate processing apparatus further includes: a bubble generating unit configured to generate bubbles in a processing liquid supply path that supplies the processing liquid to the processing liquid supply nozzle.

In the above-described substrate processing apparatus, the bubble generating unit includes an adjusting portion configured to adjust a diameter of the bubbles.

In the above-described substrate processing apparatus, the adjusting portion changes a flow path area.

According to one aspect of the embodiment, the substrate can be uniformly etched.

Hereinafter, embodiments of a substrate processing apparatus disclosed herein will be described in detail with reference to the accompanying drawings. However, the present disclosure is not limited by the embodiments described below.

### First Embodiment

As illustrated in FIG. 1, a substrate processing apparatus 1 according to a first embodiment includes a carrier carry-in/out section 2, a lot forming section 3, a lot placing section 4, a lot transport section 5, a lot processing section 6, and a controller 100. FIG. 1 is a schematic plan view illustrating the substrate processing apparatus 1 according to the first embodiment. Here, a direction orthogonal to a horizontal direction will be described as a vertical direction.

The carrier carry-in/out section 2 is configured to perform carry-in/out of a carrier 9 containing a plurality of (e.g., 25) substrates (silicon wafers) 8 aligned vertically in a horizontal posture.

The carrier carry-in/out section 2 is provided with a carrier stage 10 on which a plurality of carriers 9 are placed, a carrier transport mechanism 11 configured to transport the carriers 9, carrier stocks 12, 13 configured to temporarily store the carriers 9 therein, and a carrier placing table 14 configured to place a carrier 9 thereon.

The carrier carry-in/out section 2 is configured to transport a carrier 9 carried from the outside into the carrier stage 10 to the carrier stock 12 or the carrier placing table 14 using the carrier transport mechanism 11. That is, the carrier carry-in/out unit 2 transports a carrier 9 containing the plurality of substrates 8 before processing in the lot processing section 6 to the carrier stock 12 or the carrier placing table 14.

The carrier stock 12 temporarily stores the carrier 9 containing the plurality of substrates 8 before being processed in the lot processing section 6.

From the carrier 9 transported to the carrier placing table 14 and containing the plurality of substrates 8 before being processed in the lot processing section 6, the plurality of substrates 8 are carried out by a substrate transport mechanism 15 which will be described later.

In addition, a plurality of substrates 8 processed in the lot processing section 6 are carried into a carrier 9 placed on the carrier placing table 14 and containing no substrate 8, from the substrate transport mechanism 15.

The carrier carry-in/out section 2 is configured to transport the carrier 9 placed on the carrier placing table 14 and containing the plurality of substrates 8 after processing in the lot processing section 6 to the carrier stock 13 or the carrier stage 10 using the carrier transport mechanism 11.

The carrier stock 13 temporarily stores the plurality of substrates 8 after processing in the lot processing section 6. The carrier 9 transported to the carrier stage 10 is carried out to the outside.

The lot forming section 3 is provided with the substrate transport mechanism 15 configured to transport a plurality of (e.g., 25) substrates 8. In the lot forming section 3, a plurality of (for example, 25) substrates 8 are transported twice by the substrate transport mechanism 15 and a lot composed of a plurality of (for example, 50) substrates 8 is formed.

In the lot forming section 3, a plurality of substrates 8 are transported from the carrier 9 placed on the carrier placing table 14 to the lot placing section 4 using the substrate transport mechanism 15, and the plurality of substrates 8 are placed in the lot placing section 4 so as to form a lot.

The plurality of substrates 8 forming the lot are simultaneously processed by the lot processing section 6. When forming a lot, the lot may be formed such that the pattern-formed surfaces of the plurality of substrates 8 face each other, or may be formed such that all the pattern-formed surfaces of the plurality of substrates 8 are oriented in one direction.

In addition, in the lot forming section 3, a plurality of substrates 8 are transported from a lot 4 processed in the lot processing section 6 and placed in the lot placing section 4 to a carrier 9 using the substrate transport mechanism 15.

The substrate transport mechanism 15 includes two kinds of substrate support units (not illustrated) configured to a plurality of substrates 8, i.e. a pre-processing substrate support unit (not illustrated) configured to support a plurality of substrates 8 before being processed and a post-processing substrate support unit (not illustrated) configured to support a plurality of substrates 8 after processing. This makes it possible to prevent, for example, particles attached to, for example, the plurality of substrates 8 before processing from being transferred to, for example, a plurality of substrates 8 after processing.

The substrate transport mechanism 15 changes the posture of the plurality of substrates 8 from the horizontal posture to the vertical posture and from the vertical posture to the horizontal posture in the middle of transport of the plurality of substrates 8.

The lot placing section 4 is configured to temporarily place (stand by), on a lot placing table 16, a lot to be transported between the lot forming section 3 and the lot processing section 6 by the lot transport section 5.

In the lot placing section 4, a carry-in side lot placing table 17 and a carry-out side lot placing table 18 are provided.

On the carry-in side lot placing table 17, a lot before processing is placed. On the carry-out side lot placing table 18, a lot after processing is placed.

A plurality of substrates 8 for one lot are arranged side by side in the vertical posture in the front and rear on each of the carry-in side lot placing table 17 and the carry-out side lot placing table 18.

The lot transport section 5 transport lots between the lot placing section 4 and the lot processing section 6 or between internal portions of the lot processing section 6.

The lot transport section 5 is provided with a lot transport mechanism 19 configured to transport a lot. The lot transport mechanism 19 includes a rail 20 disposed along the lot placing section 4 and the lot processing section 6 and a moving body 21 configured to move along the rail 20 while holding a lot.

The moving body 21 is provided with a substrate holder 22 configured to hold a lot formed of a plurality of substrates 8 arranged side by side in the vertical posture in the front and rear.

The lot transport section 5 receives a lot placed on the carry-in side lot placing table 17 with the substrate holder 22 of the lot transport mechanism 19, and delivers the received lot to the lot processing section 6.

In addition, the lot transport section 5 receives a lot processed in the lot processing section 6 with the substrate holder 22 of the lot transport mechanism 19, and delivers the received lot to the carry-out side lot placing table 18.

Further, the lot transport section 5 transports the lot within the lot processing section 6 using the lot transport mechanism 19.

The lot processing section 6 performs processings such as, for example, etching, cleaning, and drying on a lot formed of a plurality of substrates 8 arranged side by side in the vertical posture in the front and rear.

The lot processing section 6 includes two etching processing apparatuses 23 configured to perform an etching processing on the lot, a cleaning processing apparatus 24 configured to perform a cleaning processing on the lot, a substrate holder cleaning processing apparatus 25 configured to perform a cleaning processing on the substrate holder 22, and a drying processing apparatus 26 configured to perform an drying processing on the lot, in which the etching processing apparatuses 23, the cleaning processing apparatus 24, the substrate holder cleaning processing apparatus 25, and the drying processing apparatus 26 are provided side by side. In addition, the number of etching processing apparatuses 23 may be one or may be three or more without being limited to two.

The etching processing apparatus 23 includes an etching processing tank 27, a rinsing processing tank 28, and substrate lifting mechanisms 29, 30.

A processing liquid for etching (hereinafter, referred to as an “etching liquid”) is stored in the etching processing tank 27. In the rinsing processing tank 28, a processing liquid for rinsing (e.g., pure water) is stored. Details of the etching processing tank 27 will be described later.

In the substrate lifting mechanisms 29, 30, a plurality of substrates 8 forming a lot are held side by side in the vertical posture in the front and rear.

The etching processing apparatus 23 receives a lot from the substrate holder 22 of the lot transport mechanism 19 with the substrate lifting mechanism 29 and lowers the received lot by the substrate lifting mechanism 29 so as to immerse the lot in the etching liquid of the processing tank 27, thereby performing an etching processing.

Thereafter, the etching processing apparatus 23 takes out the lot from the processing tank 27 by raising the substrate lifting mechanism 29, and delivers the lot from the substrate lifting mechanism 29 to the substrate holder 22 of the lot transport mechanism 19.

Then, the etching processing apparatus 23 receives the lot from the substrate holder 22 of the lot transport mechanism 19 with the substrate lifting mechanism 30 and lowers the received lot by the substrate lifting mechanism 29 so as to immerse the lot in the processing liquid for rinsing in the processing tank 28, thereby performing a rinsing processing.

Thereafter, the etching processing apparatus 23 takes out the lot from the processing tank 28 by raising the substrate lifting mechanism 30, and delivers the lot from the substrate lifting mechanism 30 to the substrate holder 22 of the lot transport mechanism 19.

The cleaning processing apparatus 24 includes a cleaning processing tank 31, a rinsing processing tank 32, and substrate lifting mechanisms 33, 34.

In the cleaning processing tank 31, a processing liquid for cleaning (e.g., SC-1) is stored. In the rinsing processing tank 32, a processing liquid for rinsing (e.g., pure water) is stored. In the substrate lifting mechanisms 33, 34, a plurality of substrates 8 forming a lot are held side by side in the vertical posture in the front and rear.

The drying processing apparatus 26 has a processing tank 35 and a substrate lifting mechanism 36 configured to move up and down with respect to the processing tank 35.

A processing gas for drying (e.g., isopropyl alcohol (IPA)) is supplied to the processing tank 35. In the substrate lifting mechanism 36, a plurality of substrates 8 for one lot are held side by side in the vertical posture in the front and rear.

The drying processing apparatus 26 receives a lot from the substrate holder 22 of the lot transport mechanism 19 with the substrate lifting mechanism 36, lowers the received lot by the substrate lifting mechanism 36 so as to carry the lot into the processing tank 35, and performs the drying processing on the lot with the processing gas for drying which is supplied to the processing tank 35. Then, the drying processing apparatus 26 raises the lot by the substrate lifting mechanism 36, and delivers the lot subjected to the drying processing from the substrate lifting mechanism 36 to the substrate holder 22 of the lot transport mechanism 19.

The substrate holder cleaning processing apparatus 25 is configured to be able to supply a processing liquid for cleaning and a drying gas to the processing tank 37. After supplying the processing liquid for cleaning to the substrate holder 22 of the lot transport mechanism 19, the cleaning processing of the substrate holder 22 is performed by supplying the drying gas.

The controller 100 controls the operations of respective sections (the carrier carry-in/carry-out section 2, the lot forming section 3, the lot placing section 4, the lot transport section 5, and the lot processing section 6) of the substrate processing apparatus 1. The controller 100 controls the operations of respective sections of the substrate processing apparatus 1 based on signals from, for example, a switch.

The controller 100 is configured with, for example, a computer, and has a computer-readable storage medium 38. In the storage medium 38, a program for controlling various processings executed in the substrate processing apparatus 1 is stored.

The controller 100 controls the operations of the substrate processing apparatus 1 by reading and executing the program stored in the storage medium 38. In addition, the program may have been stored in the computer-readable storage medium 38 and installed from the other storage medium to the storage medium 38 of the controller 100.

The computer-readable storage medium 38 may be, for example, a hard disk (HD), a flexible disk (FD), a compact disk (CD), a magneto-optical disk (MO), or a memory card.

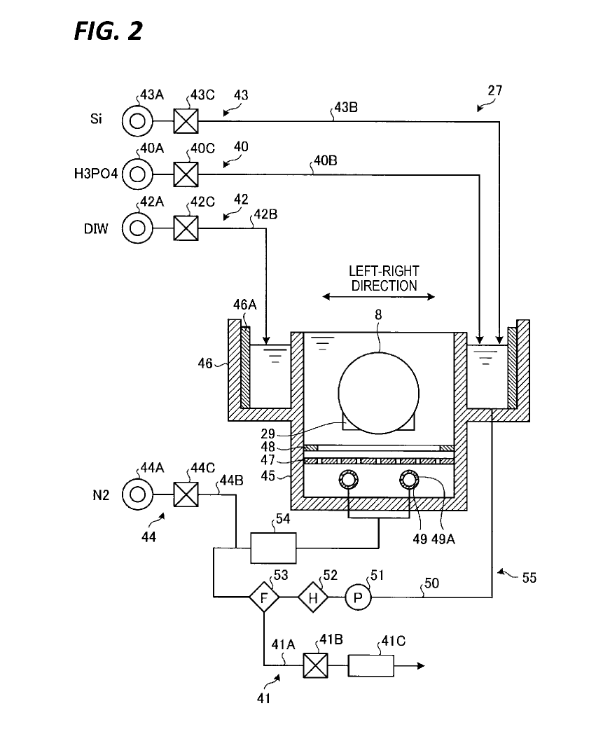

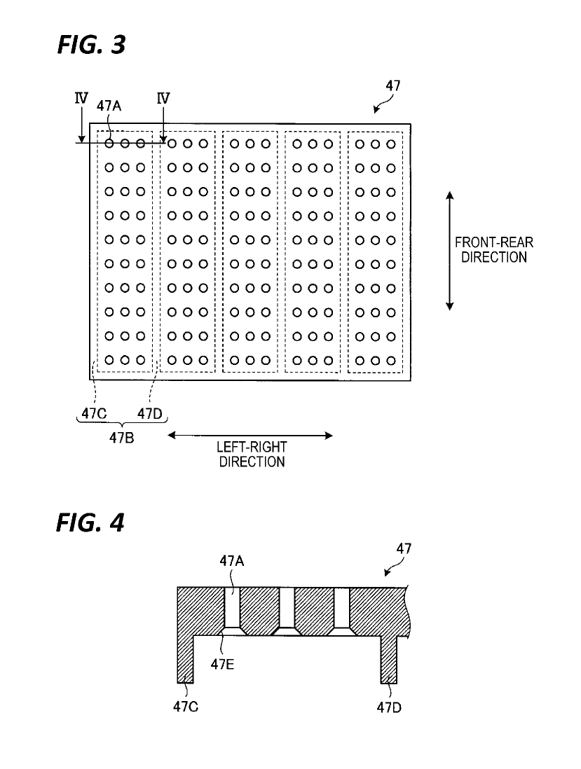

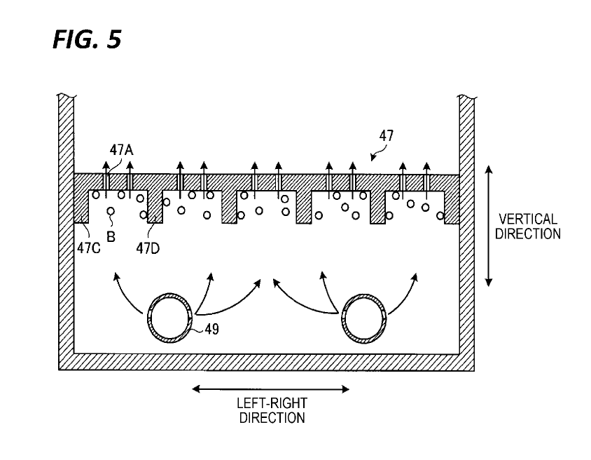

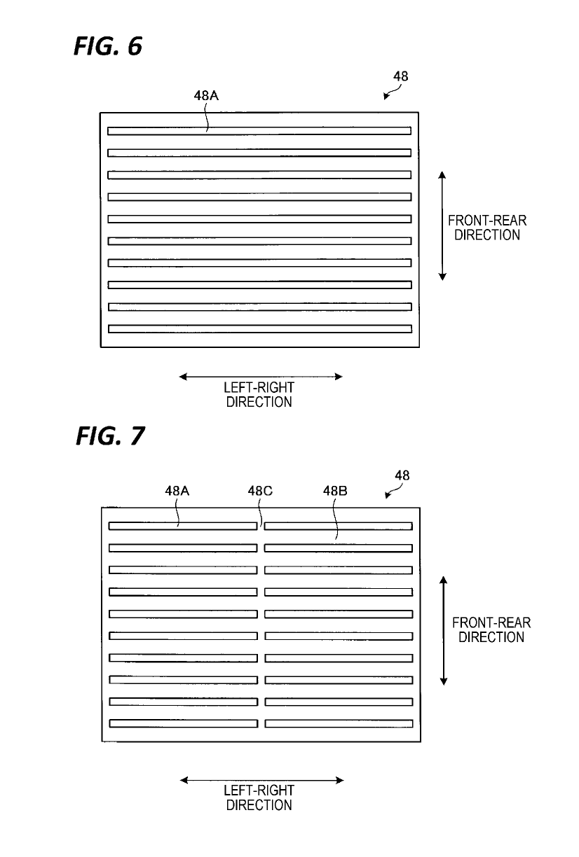

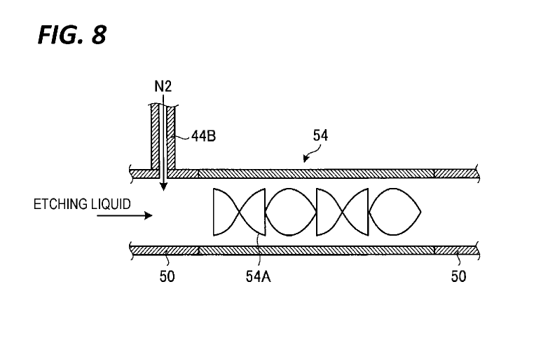

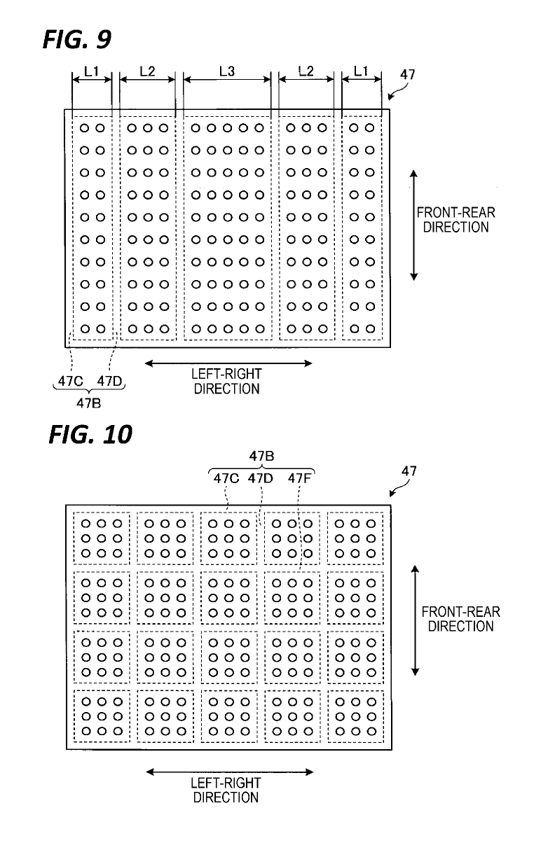

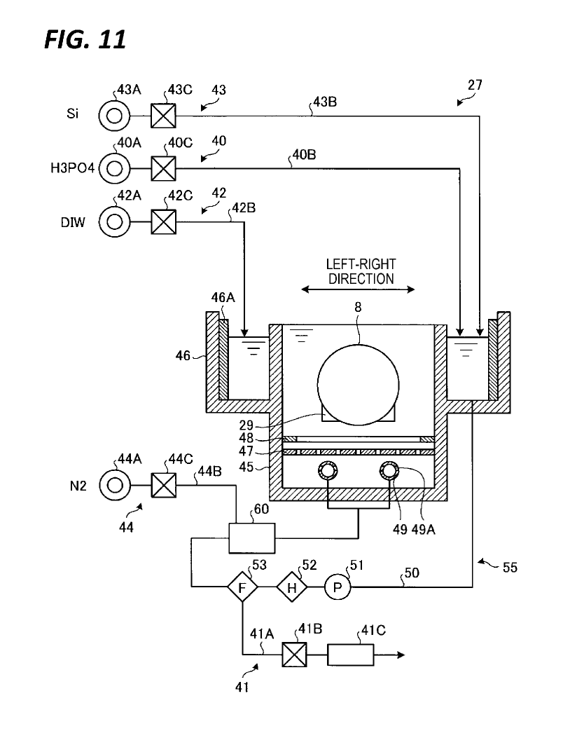

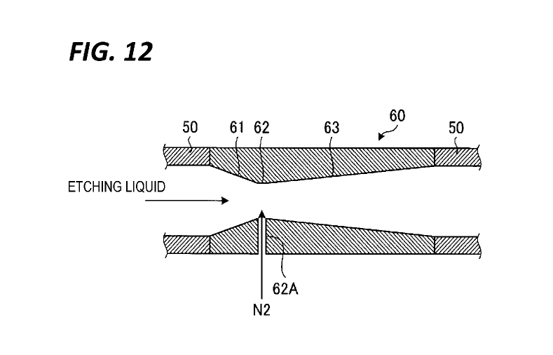

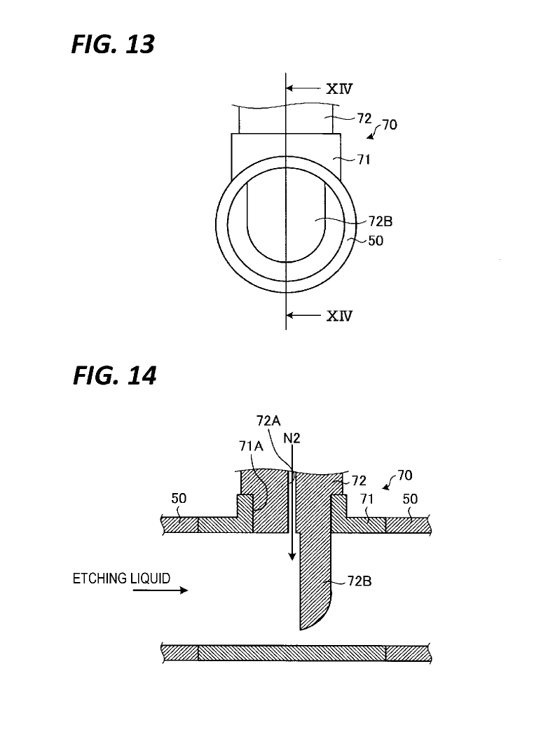

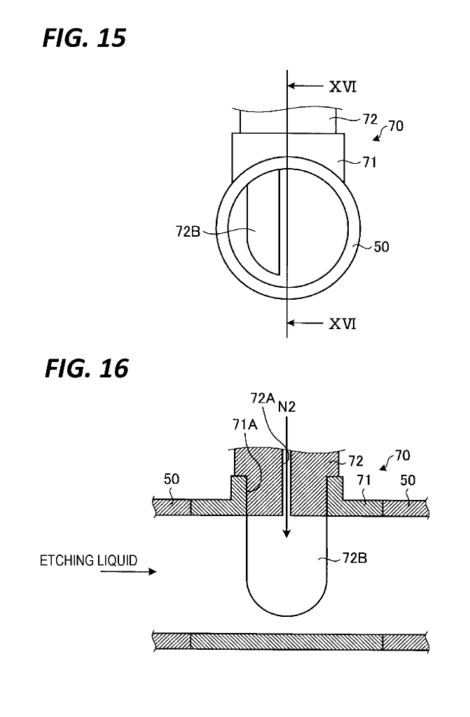

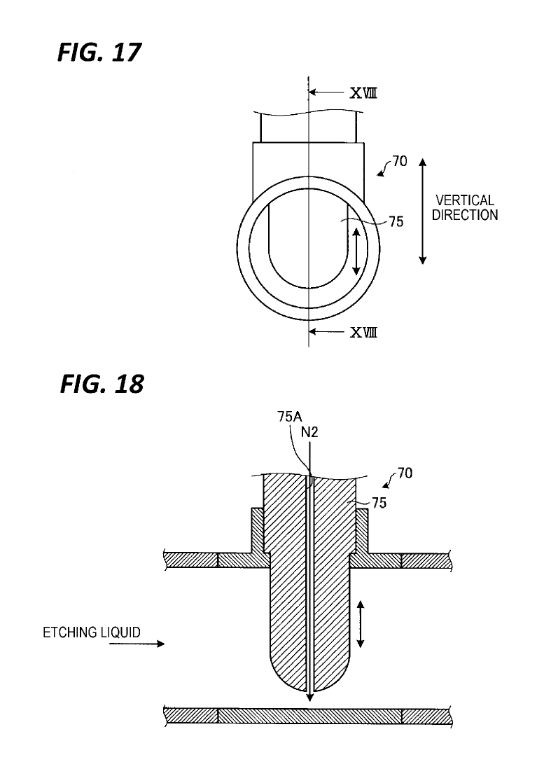

Next, the etching processing tank 27 will be described with reference to FIG. 2. FIG. 2 is a schematic block diagram illustrating the configuration of the etching processing tank 27 according to the first embodiment. Here, in the horizontal direction, a direction in which the plurality of substrates 8 are arranged in the processing bath 27, that is, a direction perpendicular to a substrate 8 will be described as a front-rear direction, and in the horizontal direction, a direction orthogonal to the front-rear direction will be described as a left-right direction.

In the present embodiment, a liquid in which a silicon solution is mixed with an aqueous solution of a predetermined concentration of a chemical agent (phosphoric acid (H₃PO₄)) (hereinafter, referred to as “phosphoric acid aqueous solution”) is used as an etching liquid. In addition, the etching liquid is not limited to the phosphoric acid processing liquid.

The etching processing tank 27 includes a phosphoric acid aqueous solution supply section 40, a phosphoric acid aqueous solution discharge section 41, a pure water supply section 42, a silicon supply section 43, a nitrogen supply section 44, an inner tank 45, an outer tank 46, a pressure regulating plate 47, and a flow regulating plate 48.

The phosphoric acid aqueous solution supply section 40 includes a phosphoric acid aqueous solution supply source 40A, a phosphoric acid aqueous solution supply line 40B, and a first flow rate regulator 40C.

The phosphoric acid aqueous solution supply source 40A is a tank configured to store the phosphoric acid aqueous solution. The phosphoric acid aqueous solution supply line 40B connects the phosphoric acid aqueous solution supply source 40A and the outer tank 46 so as to supply the phosphoric acid aqueous solution from the phosphoric acid aqueous solution supply source 40A to the outer tank 46.

The first flow rate regulator 40C is provided in the phosphoric acid aqueous solution supply line 40B so as to adjust the flow rate of the phosphoric acid aqueous solution supplied to the outer tank 46. The first flow rate regulator 40C includes, for example, an opening/closing valve, a flow rate control valve, and a flow meter.

The pure water supply section 42 includes a pure water supply source 42A, a pure water supply line 42B, and a second flow rate regulator 42C. The pure water supply section 42 supplies deionized water (DIW) to the outer tank 46 in order to replenish water evaporated by heating the etching liquid.

The pure water supply line 42B connects the pure water supply source 42A and the outer tank 46 so as to supply pure water having a predetermined temperature from the pure water supply source 42A to the outer tank 46.

The second flow rate regulator 42C is provided in the pure water supply line 42B so as to adjust the flow rate of pure water to be supplied to the outer tank 46. The second flow rate regulator 42C includes, for example, an opening/closing valve, a flow rate control valve, and a flow meter.

The silicon supply section 43 includes a silicon supply source 43A, a silicon supply line 43B, and a third flow rate regulator 43C.

The silicon supply source 43A is a tank that stores a silicon solution, for example, a silicon solution in which colloidal silicon is dispersed. The silicon supply line 43B connects the silicon supply source 43A and the temperature control tank 46 so as to supply the silicon solution from the silicon supply source 43A to the outer tank 46.

The third flow rate regulator 43C is provided in the pure water supply line 43B so as to adjust the flow rate of the silicon solution to be supplied to the outer tank 46. The third flow rate regulator 43C includes, for example, an opening/closing valve, a flow rate control valve, and a flow meter.

The nitrogen supply section 44 includes a nitrogen supply source 44A, a nitrogen supply line 44B, and a fourth flow rate regulator 44C. The nitrogen supply unit 44 supplies nitrogen as an inert gas to the etching liquid.

The nitrogen supply source 44A is a tank that stores nitrogen (N₂). The nitrogen supply line 44B connects the nitrogen supply source 44A and a circulation line 50 to be described later so as to supply nitrogen to the etching liquid flowing in the circulation line 50 from the nitrogen supply source 44A.

The fourth flow rate regulator 44C is provided in the pure water supply line 44B so as to adjust the flow rate of nitrogen to be supplied in the circulation line 50. The fourth flow rate regulator 44C includes, for example, an opening/closing valve, a flow rate control valve, and a flow meter.

The upper portion of the inner tank 45 is opened, and the etching liquid is supplied to the vicinity of the upper portion. In the inner tank 45, a lot (a plurality of substrates 8) is immersed in the etching liquid by the substrate lifting mechanism 29 so as to perform an etching processing on the substrates 8. The inner tank 45 constitutes a substrate processing tank.

Processing liquid supply nozzles 49 are provided below the inner tank 45 in the front-rear direction. Two processing liquid supply nozzles 49 are provided in the left-right direction. In addition, the number of the processing liquid supply nozzles 49 is not limited to this, and may be one or may be three or more.

A plurality of ejection ports 49A configured to eject an etching liquid containing bubbles leftwards or rightwards are formed in the processing liquid supply nozzles 49. A plurality of the discharge ports 49A are formed in the front-rear direction. The ejection ports 49A may eject the etching liquid diagonally upward to the left and diagonally upward to the right.

Further, in the inner tank 45, a pressure regulating plate 47 and a flow regulating plate 48 are provided between the processing liquid supply nozzles 49 and the substrate 8. The pressure regulating plate 47 is provided below the flow regulating plate 48. That is, the pressure regulating plate 47 is provided between the flow regulating plate 48 and the processing liquid supply nozzles 49.

The pressure regulating plate 47 and the flow regulating plate 48 are made of a chemical-resistant member such as, for example, quartz or amorphous carbon.

Now, the pressure regulating tank 47 will be described with reference to FIGS. 3 and 4. FIG. 3 is a schematic plan view illustrating the pressure regulating plate 47 according to the first embodiment. FIG. 4 is a schematic cross-sectional view taken along line IV-IV in FIG. 3.

Holes 47A are formed in the pressure regulating plate 47 in the vertical direction. A plurality of holes 47A are formed in the left-right direction and the front-rear direction so as to allow the etching liquid to flow therethrough. The pressure regulating plate 47 adjusts the inflow pressure of the etching liquid ejected from the processing liquid supply nozzles 49 (see, e.g., FIG. 2), and adjusts the inflow pressure of the etching liquid in the horizontal direction (the front-rear direction and the left-right direction). That is, the pressure-regulating plate 47 is capable of equalizing the inflow pressure of the etching liquid flowing out upward from the holes 47A. Although the shape of the holes 47A is circular, but is not limited thereto. The shape of the holes 47A may be, for example, an elliptical shape or a rectangular shape.

The pressure regulating plate 47 has ribs 47B protruding from the processing liquid supply nozzle 49 side surface (hereinafter, referred to as a “back surface”) toward the processing liquid supply nozzles 49.

The ribs 47B have a first rib 47C formed along the peripheral edge of the rear surface of the pressure regulating plate 47 and a second rib 47D formed in the front-rear direction. The first rib 47C is formed on the entire periphery of the rear surface of the pressure regulating plate 47.

A plurality of second ribs 47D are formed side by side in the left-right direction and partition the rear surface of the pressure regulating plate 47 into a plurality of regions. That is, the rear surface of the pressure regulating plate 47 is partitioned into a plurality of regions (hereinafter referred to as “partitioned regions”) by the ribs 47B. The plurality of partitioned regions are formed side by side in the left-right direction.

By partitioning the rear surface of the pressure regulating plate 47 into a plurality of partitioned regions by the ribs 47B (the first rib 47C and the second ribs 47D), as illustrated in FIG. 5, bubbles (indicated by “B”) entering the partitioned regions are prevented from moving to another partitioned region. FIG. 5 is a schematic view illustrating the state of the bubbles B contained in the etching liquid ejected from the processing liquid supply nozzles 49.

Each partitioned region is formed to include a plurality of holes 47A. A chamfered portion 47E is formed in the each of the holes 47A at the processing liquid supply nozzle 49 side opening. The chamfered portion 47E is formed on the entire circumference of the processing liquid supply nozzle 49 side opening. This makes it possible to suppress the bubbles contained in the etching liquid from remaining in the vicinity of the openings on the rear surface side of the pressure regulating plate 47 and to improve the flowability of the etching liquid in the holes 47A.

Next, the rectifying tank 48 will be described with reference to FIG. 6. FIG. 6 is a schematic plan view illustrating the flow regulating plate 48 according to the first embodiment.

A slit 48A is formed in the pressure regulating plate 48 in the left-right direction. The slit 48A is formed in a shape different from the holes 47A in the pressure regulating plate 47. A plurality of slits 48A are formed side by side in the front-rear direction. The slits 48A generate parallel flows of the etching liquid uniformly to the substrate 8 in the inner tank 45. That is, the flow regulating plate 48 rectifies the flow of the etching liquid.

A chamfered portion (not illustrated) is formed in each of the slits 48A on the processing liquid supply nozzle 49 side opening, as in the pressure regulating plate 47. The chamfered portion is formed on the entire circumference of the processing liquid supply nozzle 49 side opening. This makes it possible to prevent the bubbles contained in the etching liquid from remaining in the vicinity of the openings of the slits 48A on the processing liquid supply nozzle 49 side and to improve the flowability of the etching liquid in the slits 48A.

As illustrated in FIG. 7, the flow regulating plate 48 may be provided with a reinforcing portion formed in the front-rear direction in order to prevent the partition portions 48B partitioning the adjacent slits 48A from being deflected by the flow of the etching liquid 48C. FIG. 7 is a schematic plan view illustrating the flow regulating plate 48 according to a modification.

Referring back to FIG. 2, the outer tank 46 is provided around the upper portion of the inner tank 45 and the upper portion thereof is opened. An etching liquid overflowing from the inner bath 45 flows into the outer tank 46. Further, the outer tank 46 is supplied with pure water from the pure water supply unit 42. In addition, a silicon solution is supplied from the silicon supply unit 43 to the outer tank 46.

A heat reserving plate 46A is provided in the outer tank 46. The heat reserving plate 46A is detachably provided on the outer sidewall of the outer tank 46. The heat reserving plate 46A is made of a chemical-resistant member such as polytetrafluoroethylene (PTFE). The heat reserving plate 46A keeps the temperature of the etching liquid in the outer bank 46.

The heat reserving plate 46A also functions as an adjusting plate for changing the volume of the outer tank 46. For example, by attaching the heat reserving plate 46A, it is possible to reduce the volume of the outer tank 46 and reduce the amount of etching liquid used in the etching processing, compared with the case where the heat reserving plate 46A is not attached. Further, by attaching and detaching the heat reserving plates 46A having different thicknesses to the outer tank 46, the volume of the outer tank 46 can be adjusted, so that the amount of the etching liquid used in the etching processing can be adjusted.

The outer tank 46 and the inner tank 45 are connected by the circulation line 50. One end of the circulation line 50 is connected to the outer tank 46, and the other end of the circulation line 50 is connected to the processing liquid supply nozzle 49 installed in the inner tank 45. The circulation line 50 constitutes a processing liquid supply path.

On the circulation line 50, a pump 51, a heater 52, a filter 53, and a bubble generating unit 54 are provided in this order from the outer tank 46 side. The etching liquid in the outer tank 46 is heated by the heater 52 and flows into the inner tank 45 from the processing liquid supply nozzles 49. The heater 52 heats the etching liquid supplied to the inner tank 45 to a predetermined temperature suitable for the etching processing.

By driving the pump 51, the etching liquid is sent from the outer tank 46 to the inner tank 45 via the circulation line 50. In addition, the etching liquid overflows from the inner tank 45 and flows out to the outer tank 46 again. In this way, an etching liquid circulation path 55 is formed. That is, the circulation path 55 is formed by the outer tank 46, the circulation line 50, and the inner tank 45. In the circulation path 55, the outer tank 46 is provided on the upstream side of the heater 52 with reference to the inner tank 45.

Further, the nitrogen supply line 44B is connected to the circulation line 50 between the filter 53 and the bubble generating unit 54, and nitrogen is mixed into the etching liquid flowing in the circulation line 50.

As illustrated in FIG. 8, the bubble generating unit 54 is a static mixer, and nitrogen mixed in the etching liquid from the nitrogen supply line 44B is miniaturized by rotating a plurality of elements 54A, and bubbles having a reduced diameter are generated in the circulation line 50. FIG. 8 is a schematic configuration view illustrating the bubble generating unit 54 according to the first embodiment.

Referring back to FIG. 2, the phosphoric acid aqueous solution discharging section 41 discharges the etching liquid when all or a part of the etching liquid used in the etching processing is exchanged. The phosphoric acid aqueous solution discharge section 41 includes a discharge line 41A, a fifth flow rate regulator 41B, and a cooling tank 41C.

The discharge line 41A is connected to the circulation line 50. The fifth flow rate regulator 41B is provided in the discharge line 41A so as to adjust the discharge amount of the discharged etching liquid. The fifth flow rate regulator 41B includes, for example, an opening/closing valve, a flow rate control valve, and a flow meter. The cooling tank 41C temporarily stores and cools the etching liquid flowing thereinto through the discharge line 41A.

In addition, the opening/closing of the opening/closing valves constituting the first flow rate regulator 40C to the fifth flow rate regulator 41B and the opening degrees of the flow rate control valves constituting the first flow rate regulator 40C to the fifth flow rate regulator 41B are changed when an actuator (not illustrated) operates based on a signal from the controller 100. That is, the opening/closing valves and the flow rate control valves that constitute the first flow rate regulator 40C to the fifth flow rate regulator 41B are controlled by the controller 100.

In the substrate processing apparatus 1, the rear surface of the pressure regulating plate 47 is partitioned into a plurality of partitioned regions by the ribs 47B. Accordingly, it is possible to suppress the bubbles moving between the partitioned regions, and to suppress the occurrence of unevenness in the bubbles flowing upward through the holes 47A in the pressure regulating plate 47. For example, even when the pressure regulating plate 47 is attached in the state of being inclined in the left-right direction, the movement of air bubbles between the partitioned regions is suppressed by the ribs 47B, and the flow of the etching liquid flowing out from the holes 47A included in each of the partitioned regions is capable of being uniformized Thus, the substrate processing apparatus 1 is capable of uniformly etching the surface of the substrate 8.

In the substrate processing apparatus 1, bubbles of nitrogen are miniaturized by the bubble generating unit 54, and an etching liquid including the miniaturized bubbles is ejected from the processing liquid supply nozzles 49 to the inner tank 45. As a result, the substrate processing apparatus 1 is capable of performing the etching processing with an etching liquid including miniaturized bubbles, and thus uniformly etching a pattern formed on the substrate 8.

Further, in the substrate processing apparatus 1, the chamfered portions 47E are formed in the openings on the rear surface side of the holes 47A formed in the pressure regulating plate 47. Thus, it is possible to suppress the bubbles contained in the etching liquid from remaining in the vicinity of the openings on the rear surface side of the pressure regulating plate 47. Accordingly, the substrate processing apparatus 1 is capable of improving the flowability of the etching liquid in the holes 47A.

In the substrate processing apparatus 1, the flow regulating plate 48 is provided between the substrate 8 and the pressure regulating plate 47, and the flow of the etching liquid is regulated by the slits 48A formed on the flow regulating plate 48. As a result, the substrate processing apparatus 1 is capable of performing an etching processing using a flow-regulated etching liquid.

### Second Embodiment

Next, a substrate processing apparatus 1 according to a second embodiment will be described with reference to FIG. 9. FIG. 9 is a schematic plan view illustrating a pressure regulating plate 47 according to the second embodiment. Here, a description will be given focusing on portions different from those of the first embodiment, the same components as those in the first embodiment are denoted by the same reference numerals, and a detailed description thereof will be omitted.

In the pressure regulating plate 47, the areas of the partitioned regions decrease from the center side in the left-right direction toward both end sides in the left-right direction. That is, the area of the partitioned regions formed at the both ends in the left-right direction is smaller than the area of the other partitioned regions.

Specifically, the distances between the ribs 47B (the first rib 47C and the second rib 47D) in the left-right direction are not uniform, and the length L1 between the first rib 47C and the second rib 47D forming the partitioned regions at the both ends in the left-right direction is shorter than the lengths L2, L3 between the second ribs 47D forming the other partitioned regions.

In addition to the etching liquid, which is ejected from the ejection ports 49A of the processing liquid nozzles (see, e.g., FIG. 2) and directly flows into the partitioned regions formed at both ends in the left-right direction, the etching liquid hitting the sidewall of the inner tank 45 in the left-right direction also flows into the partitioned regions formed at both ends in the left-right direction.

Therefore, for example, when the partitioned regions formed at the both ends in the left-right direction and the other partitioned regions are set to have the same area, bubbles flowing into the partitioned regions formed at the both ends in the left-right direction increase. Thus, unevenness may occur in the bubbles flowing into respective partitioned regions.

In the substrate processing apparatus 1, in the pressure regulating plate 47, the area of the partitioned regions formed at the both ends in the left-right direction is set to be smaller than the areas of the other partitioned regions. Thus, it is possible to suppress the occurrence of unevenness in the bubbles flowing into respective partitioned regions, and thus it is possible to suppress the occurrence of unevenness in the bubbles flowing upward through the holes 47A in the pressure regulating plate 47. Thus, the substrate processing apparatus 1 is capable of uniformly etching the surface of the substrate 8. Further, the unevenness of the bubbles varies depending on the arrangement of the processing liquid supply nozzles 49 or the shape of the inner tank 45. Thus, the above-described size of the areas is an example, and the unevenness of the bubbles may be suppressed by independently setting the areas of the partitioned regions. For example, the areas of the respective partitioned areas may be set to be different from each other. Alternatively, the areas of some of the partitioned regions may be set to be different from those of other of the portioned regions.

### Third Embodiment

Next, a substrate processing apparatus 1 according to a third embodiment will be described with reference to FIG. 10. FIG. 10 is a schematic plan view illustrating the pressure regulating plate 47 according to the first embodiment. Here, a description will be given focusing on portions different from those of the first embodiment, the same components as those in the first embodiment are denoted by the same reference numerals, and a detailed description thereof will be omitted.

The pressure regulating plate 47 has, as the ribs 47B, a first rib 47C, second rib 47D formed in the front-rear direction, and third ribs 47F formed in the left-right direction. The second ribs 47D and the third ribs 47F are formed to cross each other. That is, the ribs 47B are formed in a lattice shape.

Accordingly, on the rear surface of the pressure regulating plate 47, partitioned regions partitioned in the left-right direction and the front-rear direction are formed by the ribs 47B.

In addition, in the ribs 47B, for example, the third ribs 47F may be formed in a direction inclined from the left-right direction. That is, lattice-shaped partitioned regions may be formed, but the shape of the partitioned regions is not limited. For example, the shape of the partitioned regions may be, for example, a square, a rectangle, or a parallelogram, or may be a combination of different shapes.

In the substrate processing apparatus 1, lattice-shaped ribs 47B are formed on the rear surface of the pressure regulating plate 47. Thus, the movement of bubbles in the left-right direction and the front-rear direction is suppressed in each partitioned region. Accordingly, it possible to further suppress the occurrence of unbalance in the bubbles flowing upward through the holes 47A in the pressure regulating plate 47. Thus, the substrate processing apparatus 1 is capable of more uniformly etching the surface of the substrate 8.

### Fourth Embodiment

Next, a substrate processing apparatus 1 according to a fourth embodiment will be described with reference to FIG. 11. FIG. 11 is a schematic block diagram illustrating the configuration of the etching processing tank 27 according to the fourth embodiment. Here, a description will be given focusing on portions different from those of the first embodiment, the same components as those in the first embodiment are denoted by the same reference numerals, and a detailed description thereof will be omitted.

In the substrate processing apparatus 1 according to the fourth embodiment, a venturi tube is used as a bubble generating unit 60. The nitrogen supply line 44B connects the nitrogen supply source 44A and the bubble generating unit 60.

As illustrated in FIG. 12, the bubble generating unit 60 has a diameter reduction portion 61, a mixing portion 62, and a diameter expansion portion 63. FIG. 12 is a schematic configuration view illustrating the configuration of the bubble generating unit 60 according to the fourth embodiment. In the bubble generating unit 60, the diameter reduction portion 61, the mixing portion 62, and the diameter expansion portion 63 are provided in this order along the flow direction of the etching liquid.

The diameter reduction portion 61 is connected to the circulation line 50, and formed such that the inner diameter of the pipe is decreased toward the downstream side. The mixing portion 62 is provided between the diameter reduction portion 61 and the diameter expansion portion 63, and connected to the nitrogen supply line 44B (see, e.g., FIG. 11). A hole 62A through which nitrogen supplied from the nitrogen supply line 44B flows is formed in the mixing portion 62. The nitrogen supplied through the mixing portion 62 is mixed to the etching liquid. The diameter expansion portion 63 is formed such that the inner diameter of the pipe is increased toward the downstream side.

When the pressure increases in the diameter expansion portion 63, the bubble generating unit 60 collapses nitrogen bubbles mixed in the etching liquid by the mixing portion 62, thereby miniaturizing bubbles.

In the substrate processing apparatus 1, since a venturi tube is used as the bubble generating unit 60, nitrogen bubbles mixed in the etching liquid are miniaturized. Thus, the substrate processing apparatus 1 is capable of uniformly etching a pattern formed on the substrate 8.

### Fifth Embodiment

Next, a substrate processing apparatus 1 according to a fifth embodiment will be described with reference to FIGS. 13 and 14. FIG. 13 is a schematic front view of a bubble generating unit 70 according to the fifth embodiment, as viewed in the flow direction of the etching liquid. FIG. 14 is a schematic cross-sectional view taken along line XIV-XIV in FIG. 13. Here, a description will be given focusing on portions different from those of the fourth embodiment, the same components as those in the first embodiment are denoted by the same reference numerals, and a detailed description thereof will be omitted.

In the substrate processing apparatus 1 according to the fifth embodiment, a venturi tube having a changeable flow path area is used as a bubble generating unit 70. The flow path area is an area of a plane perpendicular to the flow direction of the etching liquid.

The bubble generating unit 70 has a support portion 71 and a mixing portion 72. The support portion 71 is formed in a tubular shape and connected to the circulation line 50. An insertion hole 71A into which a portion of the mixing portion 72 is inserted is formed in the support portion 71. The support portion 71 rotatably supports the mixing portion 72. The support portion 71 forms a flow path through which the etching liquid flows while rotatably supporting the mixing portion 72.

The mixing portion 72 is connected to the nitrogen supply line 44B (see, e.g., FIG. 11). A hole 72A through which nitrogen supplied from the nitrogen supply line 44B flows is formed in the mixing portion 72. The mixing portion 72 has a plate-shaped throttle portion 72B protruding into the support portion 71 forming the flow path through which the etching liquid flows. The throttle portion 72B constitutes an adjusting portion.

When the mixing portion 72 rotates, the throttle portion 72B rotates together with the mixing portion 72, and as illustrated in FIGS. 13 to 16, the flow path area is changed in accordance with the rotation. The bubble generating unit 70 of FIGS. 13 and 14 is in a state in which the flow path area is decreased by the throttle portion 72B. FIG. 15 is a view illustrating the bubble generating unit 70 in which the mixing portion 72 has been rotated by 90 degrees from the state illustrated in FIG. 13. FIG. 16 is a schematic cross-sectional view taken along line XVI-XVI in FIG. 15.

By rotating the throttle portion 72B by 90 degrees from the state illustrated in FIG. 13, the flow path area is increased as illustrated in FIG. 15.

The bubble generating unit 70 is capable of changing the diameter of bubbles to be generated by changing the flow path area by the throttle portion 72B. For example, in a state where the flow path area illustrated in FIGS. 13 and 14 is small, bubbles are further miniaturized and the diameter of bubbles is decreased compared to the state in which the flow path area illustrated in FIGS. 15 and 16 is large.

The mixing portion 72 may be rotated by an actuator such as, for example, a motor, or may be rotated manually. In addition, the rotational position of the mixing portion 72, that is, the flow path area defined by the throttle portion 72B may be appropriately set according to the diameter of the bubbles to be generated.

In the substrate processing apparatus 1, by rotating the throttle portion 72B, it is possible to change the flow path area and it is possible to change the diameter of the bubbles generated by the bubble generating unit 70. Accordingly, it is possible to change the diameter of bubbles contained in the etching liquid depending on the contents of the etching processing (e.g., a pattern formed on the substrate 8 or the type of the etching liquid). Therefore, the substrate processing apparatus 1 is capable of performing the etching processing with an etching liquid containing bubbles having a diameter suitable for the etching processing. Further, since the diameter of bubbles is capable of being changed by rotating the mixing portion 72, the substrate processing apparatus 1 is capable of easily adjusting the diameter of bubbles.

As illustrated in FIGS. 17 and 18, in the bubble generating unit 70, a rod-shaped mixing portion 75 in which a hole 75A through which nitrogen flows is formed may protrude into the flow path, and the flow path area may be changed by changing protrusion amount of the mixing portion 75 protruding into the flow path. FIG. 17 is a schematic front view of the bubble generating unit 70 according to a modification, as viewed in the flow direction of the etching liquid. FIG. 18 is a schematic cross-sectional view taken along line XVIII-XVIII in FIG. 17. For example, the bubble generating unit 70 changes the flow path area by vertically moving the mixing portion 75. Thus, the substrate processing apparatus 1 is capable of changing the diameter of bubbles contained in the etching liquid. The protrusion amount of the mixing portion 75 may be changed by an actuator such as, for example, a motor or may be changed manually. The mixing portion 75 constitutes an adjusting portion.

In the bubble generating unit 70 according to the modification, by exchanging mixing portions 75 having different lengths, the projection amount may be changed and the flow path area may be changed.

In addition, the above-described embodiments may be appropriately combined and applied. For example, the substrate processing apparatus 1 may include a pressure regulating plate 47 illustrated in FIG. 9 and a bubble generating unit 70 illustrated in FIGS. 13 and 14.

Further, in the above embodiments, bubble generating units 54, 60, 70 are provided in the circulation line 50, and the etching liquid containing bubbles is ejected from the processing liquid supply nozzles 49, but the present disclosure is not limited thereto. For example, a bubble generating nozzle may be provided in the inner tank 45 separately from the processing liquid supply nozzles 49, nitrogen is supplied from the nitrogen supply unit 44 to the inner tank 45 via the bubble generating nozzle, bubbles may be generated in the inner tank 45.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing apparatus comprising:
a substrate processing tank;
a processing liquid supply nozzle provided in a lower portion within the substrate processing tank, and configured to eject a processing liquid from a plurality of ejection ports; and
a pressure regulating plate provided between the processing liquid supply nozzle and a substrate in the substrate processing tank having a plurality of holes through which the processing liquid flows, and configured to adjust an inflow pressure of the processing liquid ejected from the processing liquid supply nozzle,
wherein the pressure regulating plate includes ribs that protrude from a processing liquid supply nozzle side surface thereof so as to partition the processing liquid supply nozzle side surface into a plurality of partitioned regions.

2. The substrate processing apparatus of claim 1, wherein the pressure regulating plate includes the ribs in a lattice shape.

3. The substrate processing apparatus of claim 1, wherein, among the plurality of partitioned regions, areas of some of the partitioned regions are different from those of other of the portioned regions.

4. The substrate processing apparatus of claim 1, wherein the plurality of partitioned regions have different areas from each other.

5. The substrate processing apparatus of claim 1, wherein, among the plurality of partitioned regions, a partitioned region on a sidewall side of the substrate processing tank has an area smaller than areas of the other partitioned regions.

6. The substrate processing apparatus of claim 1, wherein the pressure regulating plate has a chamfered portion at an end of each of the holes on the processing liquid supply nozzle side.

7. The substrate processing apparatus of claim 1, further comprising:
a flow regulating plate provided between the pressure regulating plate and the substrate and having a slit, and configured to regulate a flow of the processing liquid to the substrate.

8. The substrate processing apparatus of claim 1, further comprising:
a bubble generator configured to generate bubbles in a processing liquid supply path that supplies the processing liquid to the processing liquid supply nozzle.

9. The substrate processing apparatus of claim 8, wherein the bubble generator includes an adjusting portion configured to adjust a diameter of the bubbles.

10. The substrate processing apparatus of claim 9, wherein the adjusting portion changes a flow path area.
